(19) United States
(12) Patent Application Publication
(10) Pub. No.: US 2014/0273533 A1
(43) Pub. Date: Sep. 18, 2014

(54) Semiconductor Annealing Method Utilizing a Vacuum Environment

(71) Applicant: Taiwan Semiconductor Manufacturing Company, Ltd., Hsin-Chu (TW)

(72) Inventors: Jen-Chan Tsun, Taoyuan County (TW); Ta-Lu Cheng, Taoyuan County (TW); Lee-Te Tseng, Hsinchu City (TW); Yi-Hann Chen, Hsinchu City (TW); Ming-Te Chen, Hsinchu City (TW)

(73) Assignee: Taiwan Semiconductor Manufacturing Company, Ltd., Hsin-Chu (TW)

(21) Appl. No.: 14/210,962

(22) Filed: Mar. 14, 2014

Related U.S. Application Data
(60) Provisional application No. 61/799,424, filed on Mar. 15, 2013.

(51) Int. Cl. H01L 21/42; H01L 21/67

(52) U.S. Cl. CPC H01L 21/42; H01L 21/67115
USPC 438/795; 392/416

(57) ABSTRACT

A semiconductor annealing method and system uses a vacuum pump to produce a vacuum environment in the annealing chamber to thereby remove undesired gas element influences. A control system obtains pressure and temperature measurements from the annealing chamber to control operation of the heating elements and vacuum pump to thereby maintain process integrity.

### PRIORITY

This application is a Non-Provisional of and claims priority to Provisional Patent Application No. 61/799,424 entitled, “SEMICONDUCTOR ANNEALING PROCESS UTILIZING A VACUUM ENVIRONMENT,” filed Mar. 15, 2013, also naming Jen-Chan Tsun et al. as inventors, the disclosure of which is hereby incorporated by reference in its entirety.

### BACKGROUND

Various kinds of annealing tools (soak, spike, milli-second, etc.) have been developed for different purposes. However, they all have disadvantages. For advanced technologies, not only is thermal control important, but also chamber ambience regulation. Current annealing tools all have gas (O₂, N₂ or other gases) present within the process chamber during processing. As a result, ambience control and particle issues arise which detrimentally affect the annealing process. For sub- or milli-second annealing, the release of mass thermal power within a very short time causes serious turbulence that produces accumulated particles on the wafer surface. With regard to ambience control, oxide-sensitive processes usually use mass flow controllers (MFCs) and N₂-refilling to reduce O₂ concentration. However, residual O₂ still has a certain level influence. Also, consistent ambiance control (including chamber matching) is difficult.

Accordingly, there is a need in the art for an annealing process which alleviates or eliminates the disadvantages described above.

### BRIEF DESCRIPTION OF THE DRAWINGS

The present disclosure is best understood from the following detailed description when read in conjunction with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a block diagrammatical view of a semiconductor annealing system utilizing a vacuum chamber according to certain illustrative embodiments of the present disclosure;

FIG. 2 is a flow chart of a semiconductor annealing method performed in accordance to certain illustrative methods of the present disclosure; and

FIG. 3 is a flow chart of block 206 of FIG. 2, according to a more detailed illustrative method of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

As described herein, illustrative embodiments of the present disclosure utilize a vacuum environment during the annealing process to eliminate and/or alleviate the problems caused by annealing chamber gases. In a generalized embodiment, a semiconductor annealing system includes an annealing chamber, heating element, and a vacuum pump connected to the annealing chamber to thereby establish a vacuum environment in the chamber. A control system is connected to the system to control the vacuum pressure using temperature and pressure measurements obtained from sensors positioned inside the annealing chamber. The control system utilizes a control loop to maintain the temperature and air pressure as dictated by the wafer recipe. Through use of the vacuum environment, the O₂ or other undesired gas element influence on the wafer is eliminated. In addition, the particle issues caused by gas turbulence during sub or milli-second annealing are eliminated. As a result, particle performance and gas element sensitive process quality (oxide-sensitive like a high-k dielectric (HK) process, for example) are improved.

With reference to FIG. 1, certain illustrative embodiments of the present disclosure will now be described. FIG. 1 illustrates a first illustrative embodiment of a semiconductor annealing system 100 of the present disclosure utilized in a front side annealing process. Semiconductor annealing system 100 comprises an annealing chamber 102 in which to anneal a semiconductor wafer 116; heating elements 112,114 to heat semiconductor wafer 116; and a vacuum pump system 118 operationally coupled to annealing chamber 102 via conduit 113.

As understood in the art, semiconductor wafer 116 includes a substrate such as, for example, a silicon substrate. Alternatively or additionally, the semiconductor substrate may include an elementary semiconductor including germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP, or combinations thereof. Furthermore, the substrate may also be a semiconductor on insulator. Moreover, the substrate may include a variety of interconnections and/or integrated circuits and components. A plurality of conductive elements may be disposed within the substrate, which may be comprised of a number of conductive metals, sizes, dimensions, etc., as would be understood by those ordinarily skilled in the art having the benefit of this disclosure. Moreover, semiconductor wafer 116 may further include various layers that are not separately depicted and that combine to form various microelectronic elements such as, for example, transistors, diodes, gates, dielectric layers, doped regions, logic devices, etc.

As shown in FIG. 1, annealing process chamber 102 comprises a heating element 112 (e.g., lamp) positioned above semiconductor wafer 116. Another heating element 114 is positioned below semiconductor wafer 116 to heat the bottom of wafer 116. Heating elements 112,114 heat semiconductor wafer 116 during annealing, as will be understood by those ordinarily skilled in the art having the benefit of this disclosure.

Annealing chamber 102 further includes a slit valve door 106 in which to position semiconductor wafer 116 in annealing chamber 102. As will be described in more detail below, a plurality of temperature and pressure sensors are positioned inside annealing chamber 102 in order to provide pressure/temperature measurements to a control system that controls the pressure and temperature of chamber 102. In this illustrative embodiment, two air pressure sensors 104 and one temperature sensor 107 are provided. Pressure sensors 104 may be, for example, an ion gauge, while temperature sensor 107 may be, for example, a pyrometer to detect the temperature of wafer 116 or chamber 102. In certain embodiments, air pressure sensors 104 are positioned near door 107 and exhaust opening 109 that feeds into conduit 113 because it is at this area that gas leakage is more likely to occur. However, in alternative embodiments, the sensors may be positioned in other areas.

A vacuum pump system 118 is operably coupled to chamber 102, via conduit 113, to provide the vacuum environment during the annealing process. In this embodiment, vacuum pump system 118 could contain several different vacuum level pumps such as, for example, a rough pump, turbo pump and cryo pump. In one illustrative embodiment, vacuum pump system 118 may have different vacuum level working stages. For example, at a first stage, the rough pump may operate at about 1 atm˜1E-3 torr; at a second stage, the turbo pump may operate at about 1E-2 torr˜1E-5 torr; and at a third stage, the cryo pump may operate at about 1E-4˜1E-7 torr. Note, however, this is but one illustrative system, as there is no requirement for multiple stages. Such design considerations will be dependent upon requirements. Because the vacuum environment may be created in stages 1→2→3 this illustrative vacuum pump system 118 may have three options (e.g., rough pump only, rough pump and turbo pump only, or the rough, turbo and cryo pumps). Furthermore, the number of each kind of pump is not restricted, as two rough pumps, one turbo pump, and two cryo pumps, etc., may be utilized for example.

In certain other illustrative embodiments, the vacuum level of pump 118, and thus the air pressure in chamber 102, can be adjusted as necessary for the recipe of semiconductor wafer 116. In general, however, less than 0.076 torr can effectively restrain oxidation. In certain embodiments, it may be necessary to achieve lower pressure for better process control; thus, the use of a turbo and/or cryo pump may be necessary. Such a determination would depend upon how the size of the product process window. With the process window allowance, a higher pressure setting in the recipe (e.g., 0.076˜0.050 torr) can save more process time. For example, the vacuum level of pump 18 may be adjusted to under 0.076 torr (based on the assumption of 1/100 oxide growth rate can effectively restrain oxidation) or smaller according to wafer recipe requirement.

A control system 108 is operationally coupled to vacuum pump system 118, pressure/temperature sensors 104,107, and heating elements 112,114 to thereby control operation of semiconductor annealing system 100. Control system 108 includes a first controller 122 that applies a temperature close loop control, a second controller 120 that applies a pressure close loop control, and a main controller 110 that maintains overall control of the air pressure and temperature profile as dictated by the wafer recipe.

Although not shown, in certain embodiments control system 108 includes at least one processor and a non-transitory and computer-readable storage, all interconnected via a system bus. Software instructions executable by the processor for implementing the illustrative methods described herein in may be stored in local storage or some other computer-readable medium. It will also be recognized that the same software instructions may also be loaded into the storage from a CD-ROM or other appropriate storage media via wired or wireless methods.

Moreover, those ordinarily skilled in the art will appreciate that various aspects of the disclosure may be practiced with a variety of computer-system configurations, including hand-held devices, multiprocessor systems, microprocessor-based or programmable-consumer electronics, minicomputers, mainframe computers, and the like. Any number of computer-systems and computer networks are acceptable for use with the present disclosure. The disclosure may be practiced in distributed-computing environments where tasks are performed by remote-processing devices that are linked through a communications network. In a distributed-computing environment, program modules may be located in both local and remote computer-storage media including memory storage devices. The present disclosure may therefore, be implemented in connection with various hardware, software or a combination thereof in a computer system or other processing system.

FIG. 2 is a flow chart of a semiconductor annealing method 200 performed in accordance to certain illustrative methods of the present disclosure. Referring to FIGS. 1 and 2, semiconductor wafer 116 is positioned inside annealing chamber 102 at block 202. This may be accomplished via manual or automated techniques. At block 204, control system 108 activates vacuum pump 118 to alter the air pressure inside chamber 102 to thereby create a vacuum environment that removes undesired gas elements from chamber 102 via conduit 113. At block 206, control system 108 activates heating element 112,114 to begin heating semiconductor wafer 116.

In order to control annealing of a given wafer 116, control system 108 continuously compares air pressure and temperature measurements to the recipe of wafer 116. As understood in the art, the wafer recipe will dictate the temperature necessary to apply to wafer 116, as well as the pressure of chamber 102. To achieve this in more illustrative method, main controller 110 (via first controller 122) controls operation of heating elements 112,114 via wired or wireless output link A. At the same time, main controller 110 receives temperature measurements of chamber 102 and/or semiconductor wafer 116 via wired or wireless input link B. Main controller 110 also controls the pressure of chamber 102 using vacuum pump 118 via wired or wireless input link C and output link D. Input links C are coupled to pressure sensors 104 to receive and process pressure measurements, while output link D is coupled to vacuum pump system 118 to provide the vacuum pressure necessary to remove the unwanted gas elements from chamber 102. Ultimately, all operations are controlled by main controller 110 via wired/wireless links E that provide coupling to first and second controllers 122,120.

FIG. 3 is a flow chart of block 206 of FIG. 2, according to a more detailed illustrative method of the present disclosure. To control the annealing process, control system 108 detects the pressure inside annealing chamber 102 via pressure sensors 104, which provide continuous real-time pressure measurement data at block 206A. Also, at bock 206A, control system 108 detects the temperature inside annealing chamber 102 using temperature sensor 107, which provide continuous real-time temperature measurement data. At block 206B, control system 108 then compares the pressure/temperature data to the wafer recipe. If, at block 206B, control system 108 determines the pressure/temperature data matches the recipe, the pressure and temperature of chamber 102 is maintained and the algorithm loops back to block 206A. If, however, at block 206B, the determination is that there is not a match, the algorithm moves onto block 206C whereby control system 108 adjusts the temperature and/or pressure via the respective controllers, heating elements 112,114 and vacuum pump system 118. As the speed of pump 118 is adjusted, the vacuum pressure inside chamber 102 also adjusts accordingly, thereby removing the undesired gas element influence in chamber 102.

In certain other illustrative embodiments, the measured pressure/temperature may only have to “substantially match” the recipe (i.e., be within a certain tolerance range of the recipe). For example, in one embodiment the tolerance range may be +/−5% of the recipe temperature and pressure.

A variety of vacuum pressure levels may be applied by control system 108. As will be understood by those ordinarily skilled in the art having the benefit of this disclosure, in one example using a typical 850C rapid thermal oxide (“RTO”) under atmosphere air pressure (˜760 torr), a 20% O₂ (˜152 torr P_{O2}) oxide growth rate 0.3˜0.5 A/sec in present in the beginning. Taking into account that the oxide growth rate and square root of P_{O2} are in direct proportion, and assuming that a 1/100 oxide growth rate can effectively retrain oxidation, the illustrative embodiments of the present disclosure will employ an air pressure of <0.076 torr. in one embodiment. However, other illustrative embodiments of the present disclosure may use other vacuum air pressure levels as dictated by the implemented system design/process.

In other illustrative embodiments, the present disclosure can be implemented on different type of annealing tools, such as, for example, back-side anneal, “both-side lamp type” anneal, laser anneal or others. In certain further illustrative embodiments, the present inventive vacuum annealing process can be used in (1) epitaxial (EPI) anneal & HK loop anneal to avoid oxidation, and (2) Flash (milli-second) anneal process to avoid turbulence that cause particle impact.

Accordingly, illustrative methods and embodiments of the present disclosure utilize a vacuum environment during the annealing process to eliminate and/or alleviate the problems caused by annealing chamber gases. As a result of the vacuum environment, the O₂ or other undesired gas element influence on the wafer is removed from the chamber during annealing. In addition, the particle issues caused by gas turbulence during sub or milli-second annealing are eliminated. As a result, particle performance and gas element sensitive processing are improved.

In an illustrative method, a semiconductor wafer is positioned inside the anneal chamber, where its heated using heating elements positioned within the annealing chamber. During this time, a control system activates vacuum pump system to alter the air pressure inside the anneal chamber to thereby create a vacuum environment. The vacuum environment acts to suction the undesired gas elements from the annealing chamber, thereby removing the associated undesirable effects. In an illustrative embodiment, a semiconductor annealing system comprises an annealing chamber, heating element to heat the wafer, and a vacuum pump system operationally coupled to the anneal chamber to create the vacuum environments. A control system control operation of the semiconductor annealing system using a feedback loop using pressure and temperature measurements obtained from the chamber in real-time. In yet other embodiments, a semiconductor annealing system comprises processing circuitry to implement any of the methods described herein.

The foregoing outlines features of several embodiments so that those ordinarily skilled in the art may better understand the aspects of the present disclosure. Those skilled persons should appreciate that they may readily use the present disclosure as a basis for designing or modifying other processes and structures for carrying out the same purposes and/or achieving the same advantages of the embodiments introduced herein. Those ordinarily skilled in the art should also realize that such equivalent constructions do not depart from the spirit and scope of the present disclosure, and that they may make various changes, substitutions, and alterations herein without departing from the spirit and scope of the present disclosure. Therefore, it should be understood that the disclosure is not intended to be limited to the particular forms disclosed. Rather, the intention is to cover all modifications, equivalents, and alternatives falling within the spirit and scope of the disclosure as defined by the appended claims.

What is claimed is:

1. A semiconductor annealing method, comprising:
heating a semiconductor wafer positioned inside an annealing chamber; and
altering air pressure inside the annealing chamber to thereby create a vacuum environment.

2. A semiconductor annealing method as defined in claim 1, wherein altering the air pressure comprises:
detecting air pressure inside the annealing chamber;
comparing the detected air pressure with a recipe air pressure for the semiconductor wafer; and
adjusting the air pressure inside the annealing chamber to substantially match the recipe air pressure.

3. A semiconductor annealing method as defined in claim 2, further comprising detecting the air pressure using an ion gauge positioned inside the annealing chamber.

4. A semiconductor annealing method as defined in claim 2, further comprising adjusting the air pressure using a vacuum pump system operationally coupled to the annealing chamber.

5. A semiconductor annealing method as defined in claim 1, further comprising:
detecting a temperature inside the annealing chamber;
comparing the detected temperature with a recipe temperature for the semiconductor wafer; and
adjusting the temperature inside the annealing chamber to substantially match the recipe temperature.

6. A semiconductor annealing method as defined in claim 1, wherein altering the air pressure inside the annealing chamber comprises producing an air pressure of less than 0.076 torr.

7. A semiconductor annealing method as defined in claim 1, wherein altering the air pressure inside the annealing chamber removes gas element influence on the semiconductor wafer.

8. A semiconductor annealing system, comprising:
an annealing chamber in which to anneal a semiconductor wafer;
a heating element to heat the semiconductor wafer during annealing; and
a vacuum pump system operationally coupled to the annealing chamber to thereby produce a vacuum environment in the annealing chamber.

9. A semiconductor annealing system as defined in claim 8, further comprising:
a temperature sensor positioned inside the annealing chamber; and
a pressure sensor positioned inside the annealing chamber.

10. A semiconductor annealing system as defined in claim 9, further comprising a control system operationally coupled to the temperature sensor, pressure sensor and vacuum pump system to thereby control the temperature and pressure inside the annealing chamber.

11. A semiconductor annealing system as defined in claim 9, wherein:
the temperature sensor is a pyrometer;
the pressure sensor is an ion gauge; and
the vacuum pump system comprises one or more of a rough pump, turbo pump and cryo pump.

12. A semiconductor annealing system as defined in claim 8, wherein the annealing chamber is a front-side annealing chamber; back-side annealing chamber; both-side annealing chamber or laser annealing chamber.

13. A semiconductor annealing method, comprising:
heating a semiconductor wafer positioned inside an annealing chamber; and
removing gas elements from the annealing chamber.

14. A semiconductor annealing method as defined in claim 13, wherein removing the gas elements from the annealing chamber comprises producing a vacuum environment inside the annealing chamber.

15. A semiconductor annealing method as defined in claim 13, wherein removing the gas elements from the annealing chamber comprises:
detecting air pressure inside the annealing chamber;
comparing the detected air pressure with a recipe air pressure for the semiconductor wafer; and
adjusting the air pressure inside the annealing chamber to substantially match the recipe air pressure.

16. A semiconductor annealing method as defined in claim 15, further comprising detecting the air pressure using an ion gauge positioned inside the annealing chamber.

17. A semiconductor annealing method as defined in claim 15, further comprising adjusting the air pressure using a vacuum pump system operationally coupled to the annealing chamber.

18. A semiconductor annealing method as defined in claim 13, further comprising:
detecting a temperature inside the annealing chamber;
comparing the detected temperature with a recipe temperature for the semiconductor wafer; and
adjusting the temperature inside the annealing chamber to substantially match the recipe temperature.

19. A semiconductor annealing method as defined in claim 13, wherein removing the gas elements from the annealing chamber comprises removing at least one of an N₂ or O₂ gas element from the annealing chamber.

20. A semiconductor annealing method as defined in claim 13, wherein removing the gas elements from the annealing chamber comprises producing an air pressure of less than 0.076 torr in the annealing chamber.
